(19) United States
(12) Patent Application Publication
(10) Pub. No.: US 2020/0126891 A1
(43) Pub. Date: Apr. 23, 2020

(54) Combined Integration Of Phase Change Materials Into Conduction-Convection-Latent Heat Optimized Thermal Management Through Novel Geometries Enabled In Additive Manufactured Heat Sinks

(71) Applicant: BOARD OF TRUSTEES OF THE UNIVERSITY OF ARKANSAS, Fayetteville, AR (US)

(72) Inventors: David Huitink, Prairie Grove, AR (US); Ange Christian Iradukunda, Fayetteville, AR (US)

(73) Assignee: BOARD OF TRUSTEES OF THE UNIVERSITY OF ARKANSAS, Fayetteville, AR (US)

(21) Appl. No.: 16/657,792

(22) Filed: Oct. 18, 2019

Related U.S. Application Data
(60) Provisional application No. 62/748,289, filed on Oct. 19, 2018.

(51) Int. Cl. H01L 23/427; H01L 23/367; H01L 23/373; H01L 45/00

(52) U.S. Cl. CPC H01L 23/4275; H01L 23/3675; B33Y 80/00; H01L 45/06; H01L 23/373

(57) ABSTRACT

A heat removal system comprising a heat sink, a plurality of fractal-fins each having a predetermined geometry; and a plurality of phase change materials each having a predetermined geometry.

### RELATED APPLICATIONS

This application claims priority to U.S. Provisional Application Ser. No. 62/748,289 filed on Oct. 19, 2018, and is incorporated herewith in its entirety.

### STATEMENT REGARDING FEDERALLY SPONSORED RESEARCH & DEVELOPMENT

This invention was made with government support under ARL-SCAPOPS program, CCN: 0402 17318-21-0000, Award start date in 6/2018, US Army Laboratory W911NF1820087. The government has certain rights in the invention.

### INCORPORATION BY REFERENCE OF MATERIAL SUBMITTED ON A COMPACT DISC

Not applicable.

### BACKGROUND OF THE INVENTION

There have been efforts to co-optimize power electronics design for performance and reliability. The reliability of electronic modules depends to a great extent on the thermal performance of the system. As the power density of electronic modules increases, so does heat from electrical losses. This heat must be effectively dispersed or extracted to avoid degradation or device failure caused by operation over maximum allowable temperature.

The use of phase change materials (PCMs) in thermal management is well known by researchers worldwide. In the field of electronics, PCMs have also been studied for the thermal management of devices. However, previous studies have not taken the approach of combined integration of PCMs into conduction-convection-latent-heat-Optimized thermal management through novel geometries enabled by additive manufacturing. Previous works have taught away from this idea by teaching an approach of encapsulating a PCM in a separate cavity or container that is then thermally coupled to the heat-generating element via highly conductive heat spreaders such as metals, conductive meshes or heat pipes. Other studies have opted to directly apply the PCM on the hot devices as an encapsulant without any additional containers.

Topology optimization to generate novel geometries, such as Fractal fins, has been applied in different kinds of devices, including heat sinks to provide improved conductive and convective cooling for electronic devices. However, no previous work has integrated PCMs with such novel geometries to provide a thermal management solution that is co-optimized for active cooling—through conduction and convection—and for passive heat removal via PCM latent heat.

### BRIEF SUMMARY OF THE INVENTION

In one embodiment, the present invention provides a design that is able to overcome the limitations of pure PCM thermal management which lacks effective heat conduction, while still taking advantage of the benefits of temperature spike mitigation made possible through the latent heat exchange of the PCM at its melting temperature.

In another embodiment, the present invention provides a heat removal system, device, approach and method that is able to overcome the limitations of pure PCM thermal management which lacks effective heat conduction, while still taking advantage of the benefits of temperature spike mitigation made possible through the latent heat exchange of the PCM at its melting temperature.

In another embodiment, the present invention provides a heat removal system, device, approach and method that integrates phase change materials (PCMs) into conduction-convection-latent-heat-Optimized thermal management through novel geometries enabled in additive manufactured heat sinks.

In another embodiment, the present invention provides a heat removal system, device, approach and method that integrates phase change materials (PCMs) into a heat sink and provides isothermal heat management through the high latent heat and energy storage density of the integrated PCM, and thereby avoids damaging peak temperatures during transient high heat loads.

In another embodiment, the present invention provides a heat removal system, device, approach and method having a PCM wherein during heating, the PCM stores energy and releases it when heat levels subside thereby providing temperature spike relief for the system.

In another embodiment, the present invention provides a heat removal system, device, approach and method comprising a heat sink, one or more fractal-fins (or other optimized geometry) and one or more PCMs.

In another embodiment, the present invention provides a heat removal system wherein each PCM may be made of inorganic salts, salt hydrates, polyols, paraffins and sugar alcohols.

In another embodiment, the present invention provides a heat removal system comprising: a heat sink, one or more fractal-fins and one or more phase change materials.

In another embodiment, the present invention provides a heat removal system wherein one or more of the phase change materials are not the same.

In another embodiment, the present invention provides a heat removal system wherein the predefined geometries of the phase change materials vary.

In another embodiment, the present invention provides a heat removal system wherein the predefined geometries of the fractal fins vary.

In another embodiment, the present invention provides a heat removal system wherein one or more of the fractal fins are made of different materials.

It is to be understood that both the foregoing general description and the following detailed description are exemplary and explanatory only and are not restrictive of the invention, as claimed.

### BRIEF DESCRIPTION OF THE SEVERAL VIEWS OF THE DRAWINGS

In the drawings, which are not necessarily drawn to scale, like numerals may describe substantially similar components throughout the several views. Like numerals having different letter suffixes may represent different instances of substantially similar components. The drawings illustrate generally, by way of example, but not by way of limitation, a detailed description of certain embodiments discussed in the present document.

FIG. 1 illustrates an embodiment of the present invention.

FIG. 2A shows a non-PCM parallel fin heat sink.

FIG. 2B shows a PCM-based parallel fin heat sink.

FIG. 2C shows a PCM-based fractal heat sink for an embodiment of the present invention.

FIG. 3 shows the average temperature of the heat-sink source interface over time for a constant heat dissipation for the designs shown in FIGS. 2A-2C.

FIG. 4A shows an example of a topology optimized design.

FIG. 4B shows another example of a topology optimized design.

FIG. 4C shows a finned design.

FIG. 5 shows thermal measurement results for the conduction+PCM for the designs shown in FIGS. 4A-4C.

FIG. 6A shows a conduction-convection-latent heat optimized design.

FIG. 6B shows a finned design for benchmarking the design shown in FIG. 6A.

FIG. 7 shows thermal measurements results for the conduction-convection-latent heat thermal management for the designs shown in FIGS. 6A and 6B.

### DETAILED DESCRIPTION OF THE INVENTION

Detailed embodiments of the present invention are disclosed herein;

however, it is to be understood that the disclosed embodiments are merely exemplary of the invention, which may be embodied in various forms. Therefore, specific structural and functional details disclosed herein are not to be interpreted as limiting, but merely as a representative basis for teaching one skilled in the art to variously employ the present invention in virtually any appropriately detailed method, structure or system. Further, the terms and phrases used herein are not intended to be limiting, but rather to provide an understandable description of the invention.

In one embodiment, the present invention overcomes one of the key roadblocks to developing devices with increased power density by providing a system and method that is effective in the removal of heat from electrical losses (inefficiencies). Rapid temperature transients sustained during operation can be difficult to manage without over-designing the cooling mechanism for typical use using current heat sink designs that rely solely on conductive and convective heat removal. By integrating phase change materials (PCMs) into a heat sink, the present invention provides a system and method having the added advantage of isothermal heat management through the high latent heat and energy storage density of the integrated PCM, and thereby avoids damaging peak temperatures during transient high heat loads.

As a PCM undergoes a phase transition, it absorbs or releases large amounts of thermal energy in the form of latent heat. During melting, for example, the latent heat is absorbed to break the intermolecular bonds of the material for the solid-liquid transition, while keeping the material temperature constant (i.e., an endothermic reaction). A preferred embodiment of the present invention leverages the energy-storing capability of PCMs to limit peak temperatures for the heat sink.

During heating, the PCM stores energy and releases it when heat levels subside—providing some temperature spike relief for the system. There is a wide variety of PCMs that may be used, including inorganic salts, salt hydrates, polyols and paraffins. For electronic cooling applications, sugar alcohols may be used as the substance of choice due to their non-corrosive nature, commercial availability and a suitable range of melting temperatures, although other applications may be better suited for other PCM materials based on their operating temperature ranges.

Furthermore, conventional heat sinks typically consist of large surfaces to effectively exchange heat from the source to the surroundings. However, the ongoing trend of miniaturization in power electronics imposes spatial constraints on heat sink geometry. The use of optimal geometries such as fractal fins for heat sinks minimizes size, while maximizing conductive and convective heat removal. These optimal structures are determined and designed based on topology optimization using computational modeling to produce higher heat transfer capability, and lower pressure drops compared to traditional (extruded parallel fin) heat sinks of equal surface area and flow rates.

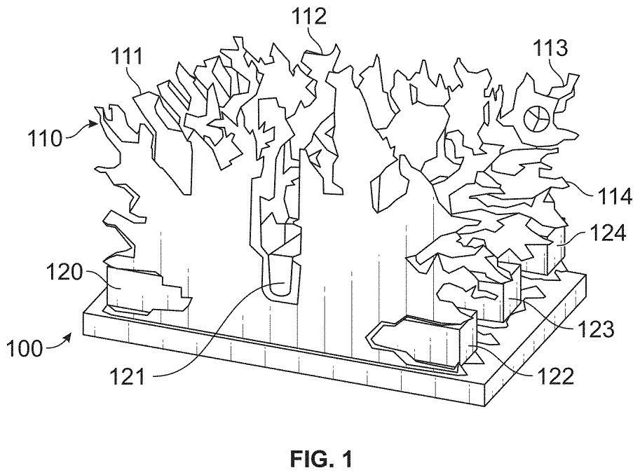

Advances in 3D printing technology have alleviated previous manufacturing constraints, making it possible to build unique heat sinks 100 as shown in FIG. 1. In a preferred embodiment heat-sink 100 may be comprised of one or more conduction-convection optimized fins (fractal fins in this instance) 110-114 and one or more PCMs 120-124. Heat sink 100 may be configured as desired. In addition, each fin may be optimized for conduction and convection with a desired geometry and material. Lastly each of the one or more PCMs may be optimized with a desired geometry and material.

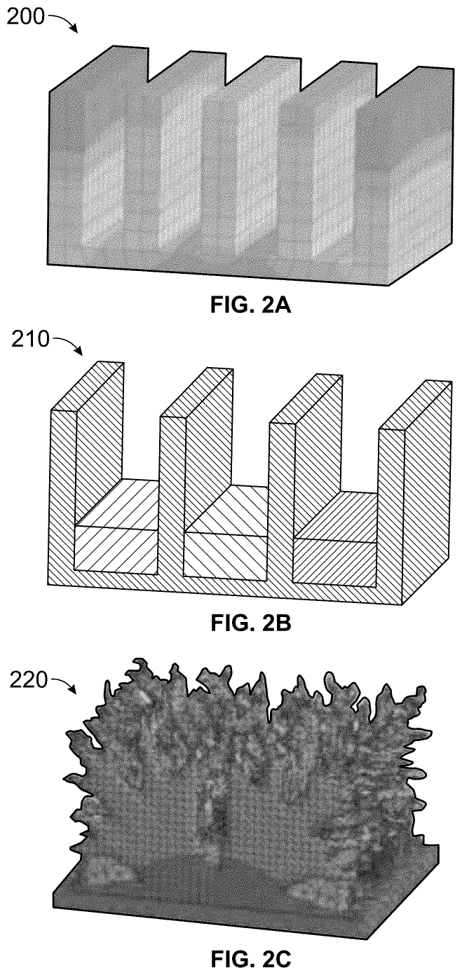

FIG. 2A shows a non-PCM parallel fin heat sink 200. FIG. 2B shows a PCM-based parallel fin heat sink 210. FIG. 2C shows a PCM-based fractal heat sink 220 for an embodiment of the present invention. An FEA study was carried out to compare the effectiveness of heat sinks 200, 210 and 220. The analysis was carried out using ANSYS software and the following summarizes the process:
Three heat sink models of equal volume (Heat Sink+PCM) were generated. The non-PCM heat sink 200 had more metallic material to compensate for the lack of PCM material.
A Transient Thermal Analysis was performed using ANSYS Mechanical
Heat Sink Material was prescribed as Aluminum, and Erythritol was used as the PCM in this particular example.
The same boundary conditions were applied to all models, including a uniform convective load of 10 W/m\hat{ }2*C on all surfaces except for the bottom surface of each heat sink.
A heat flow of 35 W was applied to the bottom face of each model.
Initial step (0.1 s) is used to establish the applied heat flow load.
Initial temperature is set at 22 C.
Second step (500 s) the heat flow is held at 35 W

Results

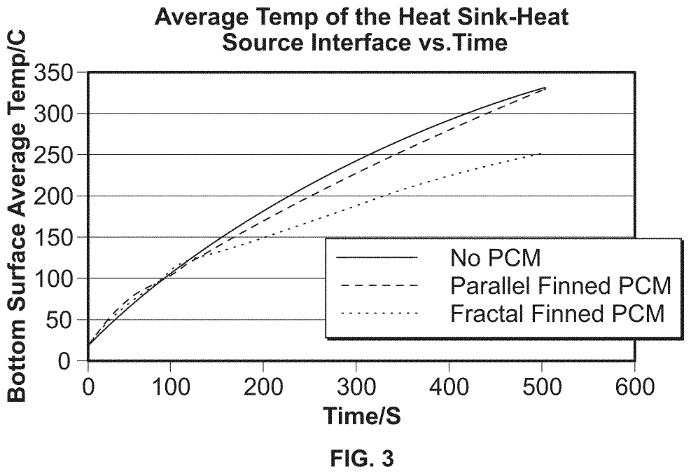

The results shown in FIG. 3 represent the average temperature over time of the bottom surface at which heat flow is applied for each heat sink design. In comparison to a heat Sink without PCMs, temperature rise for both PCM-based heat sinks slows down at around 118 C, which corresponds to Erythritol's melting point. As the PCM melts, the heat is absorbed as latent heat, providing temperature spike relief. The results also demonstrate the effectiveness of combining optimized fin geometry with PCMs. The conduction optimized fractal fins increase heat transfer rate to the PCM, resulting in the lowest temperature rise at the interface between the heat sink and the heat source. Although the PCM integrated into the parallel finned heat sink provides temperature spike mitigation, the effect is not very significant, and large temperature gradients develop across the heat sink due to the low PCM thermal conductivity. For the optimized heat sink, the fractal fins act as highly conductive paths into the PCM, increasing PCM response time and reducing temperature gradients.

Analysis of the difference between maximum and minimum temperature over the entire heat sink for each design is also shown to have improvements. Assuming a constant heat transfer coefficient over the external surfaces of each heat sink, the results indicate that, despite low PCM thermal conductivity, the optimized fractal heat sink temperature deltas are comparable to those of a purely aluminum parallel heat sink, indicating significant improvement in balancing conduction and latent heat heat removal compared to traditional applications of PCMs.

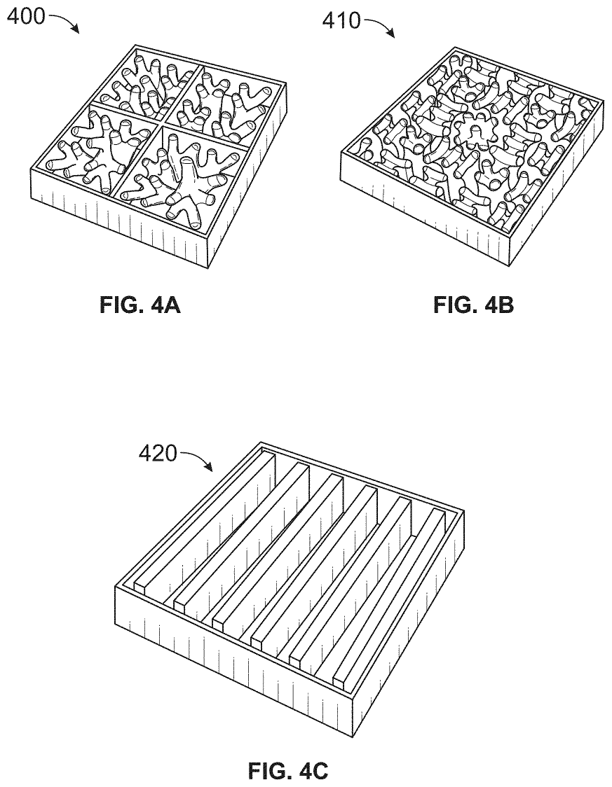

In another embodiment, sugar alcohol-based Phase Change Materials (PCM), specifically Sorbitol, is coupled with computationally generated fins to overcome the limitations of pure PCM thermal management, which lacks effective heat conduction. In doing so, the fins can provide improved heat flow paths while still taking advantage of the benefits of temperature spike mitigation made possible through the latent heat exchange of the PCM at its melting. The computationally generated fins may be manufactured out of aluminum (alloy AlSi10Mg, 10% Silicon 0.5% Mg) by additive manufacturing (AM), specifically via Direct Metal Laser Sintering (DMLS), which fuses metal powder into the complex fin geometries 400 and 410 illustrated in FIGS. 4A-4B.

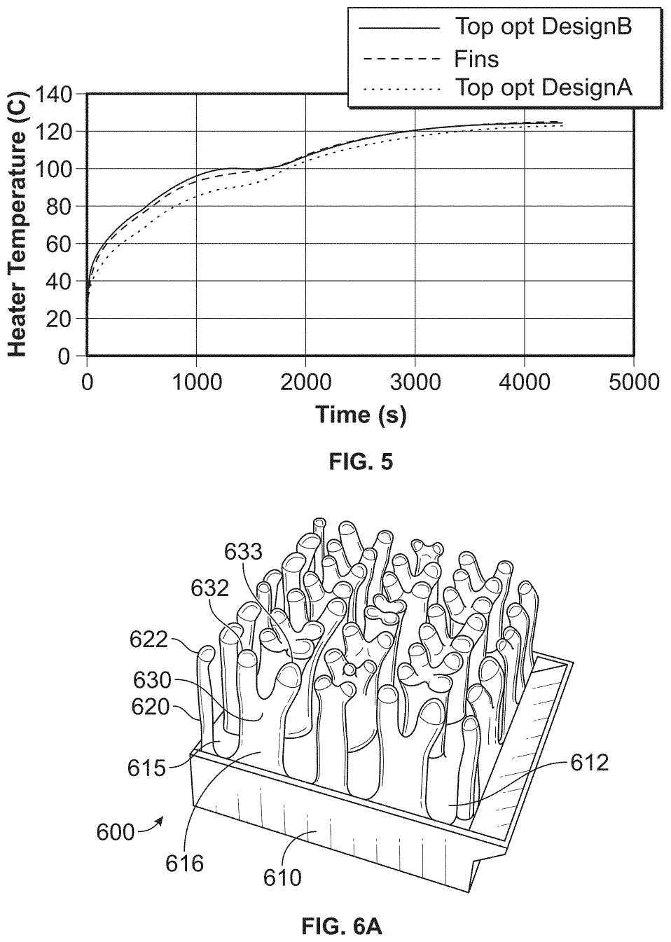

Testing was carried out to compare the effectiveness of the optimized fins 400 and 410 to standard rectangular extrusions 420, which are typically used in tandem with PCM. For a fair comparison, the rectangular fins were designed according to optimal parametric ratios reported in previous literature, and fabricated via AM to ensure uniform thermal properties across the board, particularly thermal conductivity. Additionally, weight and volume of the designs were kept identical. Under natural convection, a constant power dissipation of 5 watts was applied to the heatsink using a ceramic-based heater to simulate a semiconductor device. Insulation was added to the sidewalls of the design to force most of the heat into the PCM, leaving only the top side exposed to convection with ambient air at 20° C. Results showing heater temperature vs. time are plotted in FIG. 5, indicating improvements in balancing conduction and latent heat removal with the computationally generated geometries compared to traditional applications of PCMs using rectangular fin extrusions.

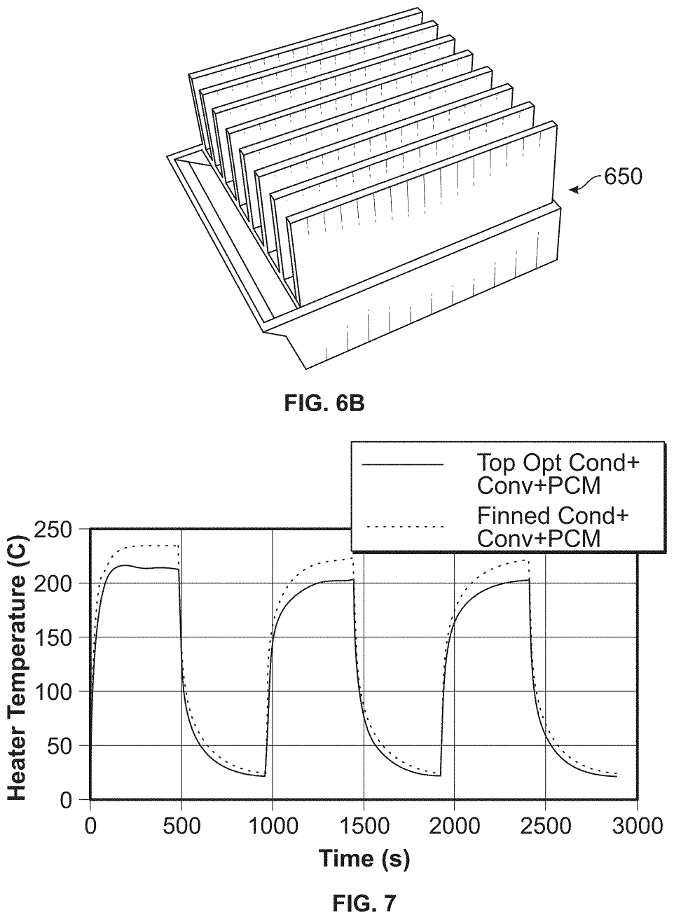

FIG. 6A shows another embodiment of the present that provides a thermal management solution with combined passive and active cooling. Heat removal system 600 includes base 610 in which one or more optimized PCM geometries 612 are located. In communication with base 610 are one or more elongated fins 615 and 616. The geometries of the fins are computationally generated and may include elongated sections 620 and 630. The distal end of fin 615 may include terminal section 622 at the end of elongated section 620. In other embodiments, elongated section 630 of fin 616 may terminate with a plurality of terminal sections 632 and 633. In a preferred embodiment, the terminal section may be bulbous.

As shown in FIG. 6A, terminal section 622 has a cross-sectional area that is greater than the cross-sectional area of elongated section 620. In addition, the width of terminal section 622 is greater than the width of elongated section 620. As also shown in FIG. 6A, terminal sections 632 and 633 extend past the edges of elongated section 630.

Additive manufacturing may be used to fabricate the computationally generated fins. The fins are configured in a stack, with the top fins topology optimized for convection and the bottom fins optimized for conduction to improve the heat transfer rate into the surrounding PCM for latent heat exchange, while also providing heat flow paths to the top level for convective heat removal.

The Conduction-Convection-Latent Heat Optimized designs of the present invention were compared to a similar stack configuration with traditional rectangular fins, whose geometries are derived from literature and commercially available heatsinks. The equal-volume designs 600 and 650 were compared in terms of their ability to limit peak temperature under an on-and-off thermal load. The thermal load is set at SOW with convection provided through a heat dissipation chamber that supplies a constant stream of air at 20° C. As indicated in FIG. 7, the computationally optimized design 600 provides improved performance in limiting temperature due to the optimal fin geometries enabled via additive manufacturing.

While the foregoing written description enables one of ordinary skill to make and use what is considered presently to be the best mode thereof, those of ordinary skill will understand and appreciate the existence of variations, combinations, and equivalents of the specific embodiment, method, and examples herein. The disclosure should therefore not be limited by the above-described embodiments, methods, and examples, but by all embodiments and methods within the scope and spirit of the disclosure.

What is claimed is:

1. A heat removal system comprising: a heat sink, one or more fractal-fins and one or more phase change materials.

2. The heat removal system of claim 1 wherein said one or more phase change materials further including a first phase change material and a second phase change material, said first and said second phase change materials are not the same.

3. The heat removal system of claim 1 further including a first phase change material having a first geometry and a second phase change material having a second geometry, said first geometry and said second geometry are not the same.

4. The heat removal system of claim 3 wherein said first phase change material and said second phase change materials are not the same.

5. The heat removal system of claim 1 further including a first fractal fin having a predefined geometry and a second fractal fin having a predefined geometry, said geometries are not the same.

6. The heat removal system of claim 1 further including a first fractal fin made of a first predetermined material and a second fractal fin made of a second predetermined material, said first and said second fractal fin materials are not the same.

7. A heat removal system comprising:
a heat sink;
one or more fractal-fins having a predetermined geometry; and
a plurality of phase change materials each having a predetermined geometry.

8. The heat removal system of claim 7 wherein each phase change material has a different geometry.

9. The heat removal system of claim 7 wherein each fractal fin has a different geometry.

10. The heat removal system of claim 7 wherein each phase change material is made of a different material.

11. The heat removal system of claim 7 wherein each fractal fin is made of a different material.

12. The heat removal system of claim 8 wherein each phase change material is made of a different material.

13. The heat removal system of claim 9 wherein each fractal fin is made of a different material.

14. The heat removal system of claim 7 wherein at least two of said plurality of phase change materials have a different geometry.

15. The heat removal system of claim 7 wherein at least two of said plurality of fractal fins have a different geometry.

16. The heat removal system of claim 14 wherein said at least two phase change material are made of a different material.

17. The heat removal system of claim 15 wherein said at least two fractal fins are made of a different material.

18. The heat removal system of claim 1 wherein said phase change material is at least one of an inorganic salt, sorbitol, salt hydrates, polyols, paraffins and sugar alcohols.

19. The heat removal system of claim 7 wherein said phase change material is at least one of an inorganic salt, sorbitol, salt hydrates, polyols, paraffins and sugar alcohols.

20. A heat removal system comprising:
a base;
a plurality of phase change materials each having a predetermined geometry located in said base; and
one or more fins each having a predetermined geometry including an elongated section connected to said base and one or more terminal sections located at the distal end of said elongated section.

21. The heat removal system of claim 19 wherein said phase change material is at least one of an inorganic salt, sorbitol, salt hydrates, polyols, paraffins and sugar alcohols.

22. The heat removal system of claim 19 wherein at least one terminal section has a cross-sectional area that is greater than the cross-sectional area of said elongated section.

23. The heat removal system of claim 19 wherein at least one terminal section has a width that is greater than the width of said elongated section.

24. The heat removal system of claim 19 wherein at least one elongated section has a distal end that includes a plurality of terminal sections that extend past the edges of said elongated section.

25. The heat removal system of claim 24 wherein at least one elongated section has a distal end that includes a plurality of terminal sections that extend past the edges of said elongated section, said terminal sections are bulbous in shape.
